(19) United States
(12) Patent Application Publication
(10) Pub. No.: US 2025/0046985 A1
(43) Pub. Date: Feb. 6, 2025

(54) APPARATUSES FOR ENHANCING ANTENNA RADIATION IN WEARABLE DEVICES

(71) Applicant: PLUME DESIGN, INC., Palo Alto, CA (US)

(72) Inventors: Miroslav SAMARDZIJA, Mountain View, CA (US); Arthur TUNG, San Jose, CA (US); Eden CHENG, Taipei City (TW); Hao-Hsiu HUANG, Taipei City (TW); Liem Hieu Dinh VO, San Jose, CA (US)

(21) Appl. No.: 18/363,116

(22) Filed: Aug. 1, 2023

(51) Int. Cl. H01Q 1/27; H01Q 1/44; H05K 1/02

(52) U.S. Cl. CPC H01Q 1/273; H01Q 1/44; H05K 1/0237; H05K 2201/10098

(57) ABSTRACT

According to some embodiments, the disclosed device includes a printed circuit board (PCB) including a radio frequency feed component; a power source including a metallic jacket; and an antenna coupling component. The antenna component can be coupled to the radio frequency feed component. The antenna component can additionally be coupled to the metallic jacket, such that radio frequency signals delivered to the antenna coupling component from the radio frequency feed component cause the metallic jacket to emit radio frequency radiation.

### BACKGROUND

Wearable devices face many design challenges, particularly around space constraints. These devices must be able to offer desired functionality in a compact form factor that is intended to be worn on a user's body. The small size requirements mean that communication antennas of many wearable devices suffer from low output, limiting the range at which these devices can communicate with other devices, such as mobile phones, base stations, and other devices that may need to communicate with a wearable device to provide end users with an optimal usage experience.

### BRIEF DESCRIPTION OF THE DRAWINGS

The accompanying drawings illustrate several example implementations and are a part of the specification. Together with the following description, these drawings demonstrate and explain various principles of the present disclosure.

FIG. 1 is a block diagram of an example device for enhancing antenna radiation in wearable devices.

FIG. 2 is a schematic diagram of example circuitry for enhancing antenna radiation in wearable devices.

FIG. 3 is a cutaway diagram of an example wearable device that includes components for enhancing antenna radiation in wearable devices.

FIG. 4 is a cutaway diagram of an additional example wearable device that includes components for enhancing antenna radiation in wearable devices.

FIG. 5 is a cutaway diagram of a further example wearable device that includes components for enhancing antenna radiation in wearable devices.

Throughout the drawings, identical reference characters and descriptions indicate similar, but not necessarily identical, elements. While the example implementations described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to apparatuses for enhancing antenna radiation in wearable devices. As will be described in greater detail below, devices that include a coupling component or bridge between a radio frequency (RF) feed and the metallic jacketing used in many batteries can effectively turn the metallic jacket of the battery into an antenna, thereby enhancing the amount of antenna radiation the wearable device can output. In a similar vein, the principles described herein can be applied to other components of a wearable device, such as a metal bezel incorporated into a smart ring or even the metallic components of the flexible printed circuit (FPC) that provides computing logic for the wearable device, to enable those components of the wearable device to likewise function as antennas for communicating with other devices. Using these components as antennas for the wearable device reduces the need for dedicated antenna components that would otherwise take up valuable space inside the housing of the wearable device, allowing for larger batteries and/or larger FPCs to maximize the number of features such as battery life that can be offered to end users.

Furthermore, the RF feed and coupling component can be capacitively or parasitically coupled to the other components such as the battery jacket or, in examples where the housing includes metallic elements capable of conducting radio frequency signals, the ring bezel. Coupling the coupling component and the battery jacket in this way can minimize the need to scrape away any insulating layers that might be applied to, e.g., the battery jacket, and likewise minimize the need for soldering that can risk damaging delicate components of the wearable device. As will be illustrated and described in greater detail below, the RF feed, coupling component, and battery jacket can form a current loop through which RF signals can propagate, causing the loop to emit RF radiation.

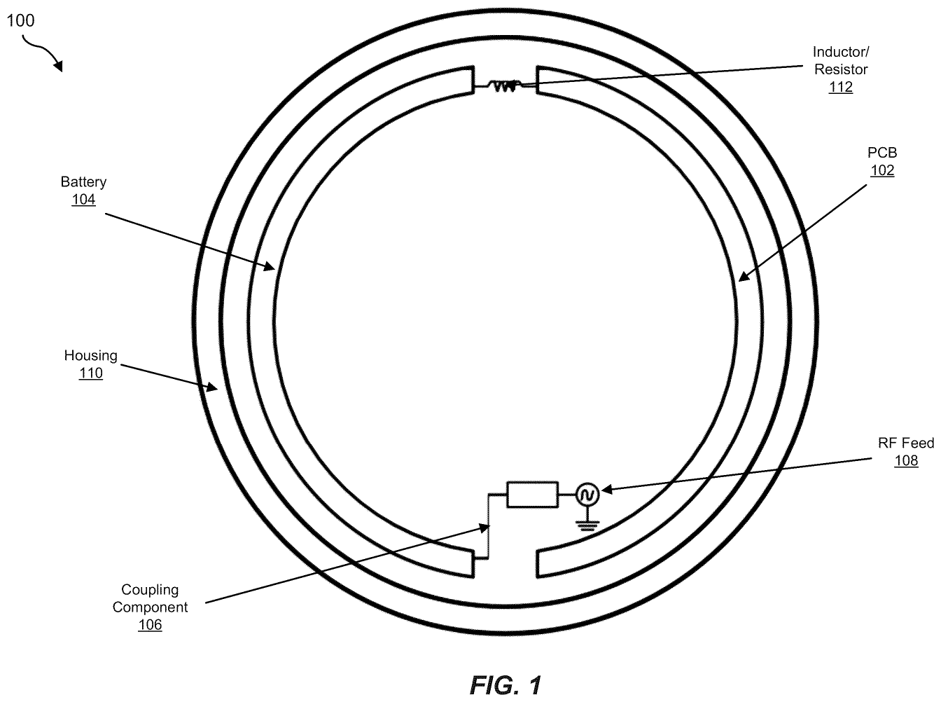

FIG. 1 is a block diagram of an example wearable device 100 that includes components for enhancing antenna radiation in wearable devices. As illustrated in FIG. 1, a wearable device can include a housing 110 dimensioned to fit around part of a user's body, such as a finger. Housing 110 can be formed from a variety of components, either alone in combination. For example, housing 110 may be formed from aluminum and polycarbonate. In further embodiments, housing 110 may be formed entirely from metal and/or entirely from a non-conductive material. The wearable device can include various other components, some or all of which can be contained inside the housing. In the example of FIG. 1, wearable device 100 includes a flexible PCB circuit (also referred to as “FPC”, illustrated as PCB 102), battery 104 that is configured to provide electric power to PCB 102 and other components of wearable device 100, at least partially via inductor/resistor 112. PCB 102 can include a variety of components, such as RF feed 108 (sometimes referred to as an antenna feed, feed line, or feeder) that is configured to generate radio frequency signals that can be fed to other components of wearable device 100 for antenna transmission. To that end, RF feed 108 can be communicatively, capacitively, and/or electrically coupled to an antenna coupling component, illustrated as coupling component 106.

Radio frequency signals and currents used by wearable devices for communicating with other devices typically involve high frequencies, such as 2.4 GHZ, though any suitable frequency may be used. In some examples, the radio frequency signals and corresponding radio frequency radiation may involve frequencies greater than 2.4 GHz. Currents oscillating at these frequencies may enable capacitive coupling (sometimes referred to as parasitic capacitance) between two closely spaced conductors, such as the structure formed by the above-described coupling component and the metallic jacket of the battery, separated by the thin nylon coating of the battery. Such capacitive coupling allows the coupled components to function as parts of a single circuit for purposes of the high-frequency oscillating signals.

Battery 104 can be configured in a variety of ways. In some embodiments, battery 104 can include a metallic casing formed from any appropriate material, such as aluminum. Additionally or alternatively, battery 104 can include an exterior protective layer that can be formed from a variety of materials, including nonconductive or insulating polymers such as nylon. As will be described in greater detail below, coupling component 106 can be capacitively coupled to the metallic casing of battery 104, thereby allowing the metallic casing of battery 104 to produce RF radiation, i.e., act as an antenna for wearable device 100, without requiring physical alterations to battery 104. In other words, the exterior protective layer of the battery (which may be nonconductive or insulating) can be disposed between coupling component 106 and the metallic casing of battery 104. Alternatively, coupling component 106 can be electrically coupled to battery 104, though this may necessitate removing at least a portion of any exterior coating present to ensure that coupling component 106 can form a robust electrical connection with the metallic casing of battery 104.

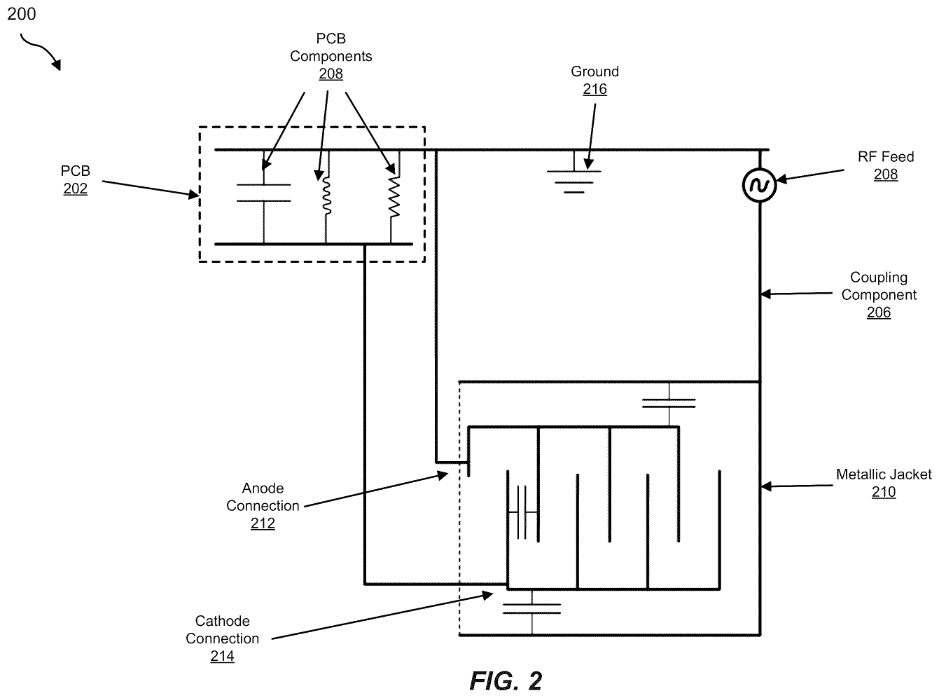

FIG. 2 is a schematic diagram of example circuitry for enhancing antenna radiation in wearable devices. As shown in FIG. 2, the internal circuitry 200 of a wearable device can include a PCB 202 that includes PCB components 208. PCB 202 can be electrically coupled to anode connection 212 and cathode connection 214 of a battery, such as battery 104 from FIG. 1. PCB 202 can also be electrically connected to ground 216 and RF feed 208. The battery can include a metallic jacket 210 that is coupled to RF feed 208 by coupling component 206. Metallic jacket 210 may be capacitively coupled to the anode and cathode of the battery, and the anode and cathode may likewise be capacitively coupled to each other, thereby allowing high frequency (i.e., radio frequency) electric signals to propagate across those components. Of particular note, RF feed 208, coupling component 206, metallic jacket 210, and ground 216 form a closed loop circuit capable of conducting electric signals, including those necessary to produce radio frequency electromagnetic radiation. These components acting in concert can therefore behave as an antenna for radio-frequency communication with other devices.

Coupling component 206 may be coupled to other parts of the battery as well. For example, coupling component 206 may be coupled to an anode region of the battery. In other examples, coupling component 206 may be coupled to a cathode region of the battery.

RF feed 208, coupling component 206, metallic jacket 210, and PCB components 208 may likewise form closed loop circuits capable of conducting high-frequency electric signals. In these examples, radio frequency signals delivered to coupling component 206 can transmit RF signals via metallic jacket 210 to some or all of PCB components 280, to, causing those components to also behave as an antenna for radio-frequency communication with other devices. Other current loops can be formed by other combinations of components, allowing those components to participate in the emission of radio-frequency EM radiation as well.

In some embodiments, the computing components of the FPC (illustrated in FIG. 2 as PCB 202 and PCB components 208) are configured to perform their computational functions using DC current at a specific voltage, such as 3.5 volts DC. The frequency of the RF signals, which can be greater than 2.4 GHz in alternating current (AC), accordingly means that the RF currents tend not to interfere with the normal operation of PCB components 208 even when they are simultaneously being used as an antenna for the mobile device.

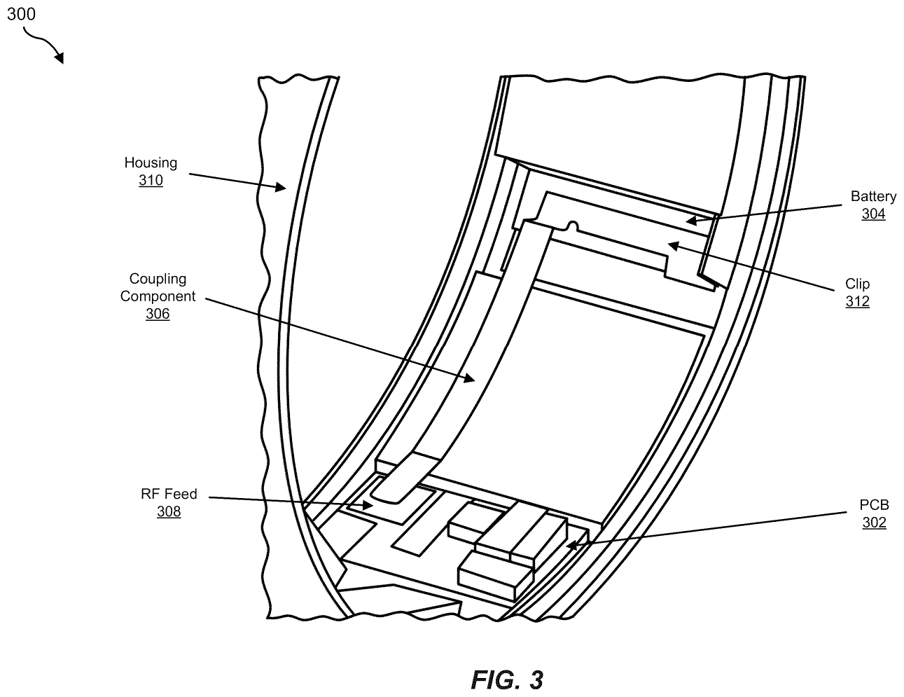

FIG. 3 is a cutaway diagram of an example wearable device 300 that includes components for enhancing antenna radiation in wearable devices. As shown in FIG. 3, wearable device 300 can include a housing 310 as described above. Inside of housing 310, wearable device 300 can include PCB 302 that includes an RF feed 308, also as described above. A coupling component 306 can be coupled to RF feed 308, whether electrically (e.g., by soldering) or capacitively. Coupling component 306 can bridge the space between PCB 302 and battery 304 and affix to battery 304 via clip 312 that is integrated into coupling component 306. Affixing coupling component 306 to battery 304 in this way can ensure solid capacitive coupling between the metallic jacket of battery 304 and clip 312 without requiring potentially dangerous and/or damaging alterations to battery 304 (such as scraping away the nylon protective layer to form an electrical connection between battery 304 and coupling component 306). However, some embodiments of the principles herein may use an electric connection between coupling component 306 and battery 304, such as situations in which battery 304 has a metallic exterior case without a non-insulating outer layer.

Coupling components can themselves function as an antenna component that emits RF radiation and can be configured to maximize the amount of desired RF radiation (i.e., RF radiation at a particular frequency, such as 2.4 GHZ) when the RF feed delivers radio frequency signals to the coupling component while minimizing the spillover into other RF bands. For example, increasing a surface area along one axis of coupling component 106 can change a peak emission frequency and/or increase a quantity of RF radiation emitted by coupling component 106. Adjusting a length of coupling component 106 with respect to the distance between the RF feed and the battery casing can likewise “tune” the resonant frequency of the high-frequency circuit that includes the coupling component and the battery casing.

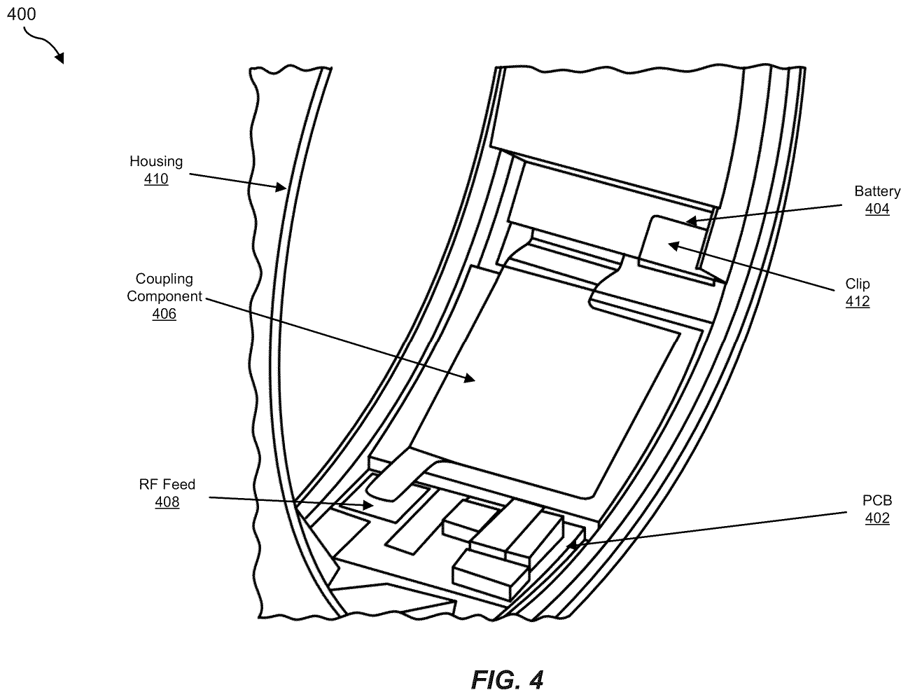

FIG. 4 is a cutaway diagram of an example wearable device 400 with an alternative coupling component, illustrated as coupling component 406. As with wearable device 300, wearable device 400 includes a housing 410, a PCB 402 that includes an RF feed 408, a battery 404, and a coupling component 406 affixed to battery 404 by clip 412. Compared to the strip-like form factor of coupling component 306 in FIG. 3, coupling component 406 includes a wide rectangular region that can function as an antenna that emits electromagnetic radiation when RF feed 408 provides RF signals to coupling component 406. Clip 412 likewise has a modified form factor compared to clip 312. Because the clip is a metallic component, the shape and configuration of the clip can likewise influence the antenna functions of coupling component 406.

In some examples, a wearable device can be formed by electrically coupling a printed flexible circuit board (PCB or FPC) that includes a radio frequency feed component to a power source that includes a metallic jacket. The method can also include coupling (whether capacitively or electrically) an antenna coupling component to both the PCB and the power source such that the antenna coupling component is coupled to the radio frequency feed component and also coupled to the metallic jacket of the power source such that radio frequency signals delivered to the antenna coupling component from the radio frequency feed component cause the metallic jacket of the power source to emit radio frequency radiation.

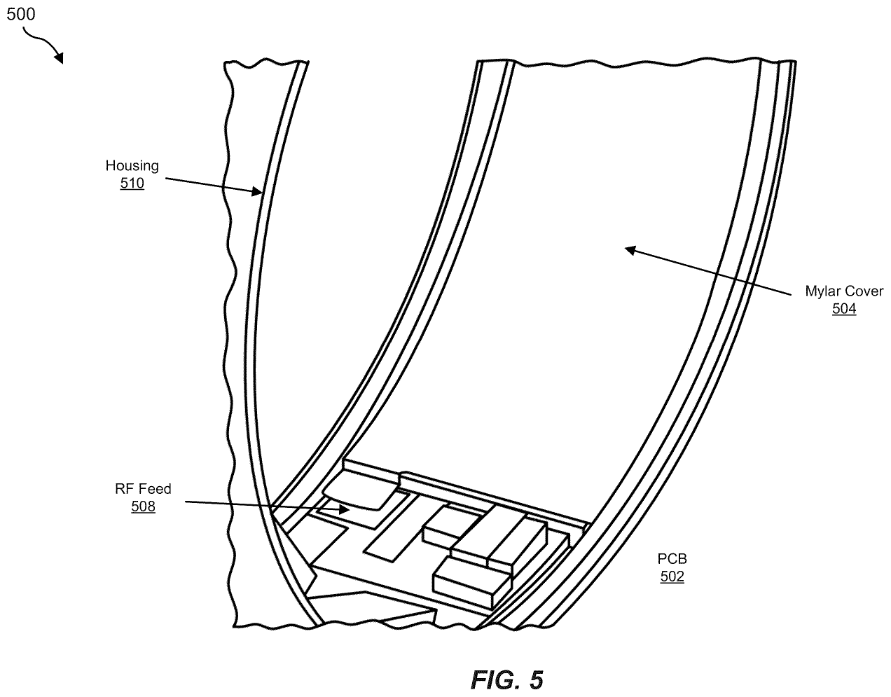

In some embodiments, some or all of the components described above can be covered with a backing to protect the components and/or reflect RF radiation in a particular direction. FIG. 5 is a cutaway diagram of an example wearable device 500 that includes a mylar cover 504 that covers the coupling component and battery (not illustrated; these components are hidden behind mylar cover 504). Mylar cover 504 can protect the coupling component and battery during the fabrication process and/or protect these components during ordinary use of the wearable device.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
a printed circuit board (PCB) comprising a radio frequency feed component;
a power source comprising a metallic jacket; and
an antenna coupling component that:
is coupled to the radio frequency feed component; and
is coupled to the metallic jacket such that radio frequency signals delivered to the antenna coupling component from the radio frequency feed component cause the metallic jacket to emit radio frequency radiation.

2. The device of claim 1, wherein the antenna coupling component is capacitively coupled to the metallic jacket.

3. The device of claim 1 wherein the antenna coupling component is electrically coupled to the metallic jacket.

4. The device of claim 1, wherein the power source is coupled to the PCB such that radio frequency signals delivered to the antenna coupling component from the radio frequency feed component cause circuitry of the PCB to emit radio frequency radiation.

5. The device of claim 1, wherein the frequency of the radio frequency radiation is equal to or is greater than 2.4 GHz.

6. The device of claim 1, further comprising a housing that is dimensioned to be worn about a finger of a user and is further dimensioned to contain the PCB, the power source, and the antenna coupling component.

7. The device of claim 6, wherein the housing comprises a metallic bezel that is capable of conducting RF signals.

8. The device of claim 1, wherein the antenna coupling component is coupled to an anode region of the power source.

9. The device of claim 1, further comprising an insulating layer disposed between the metallic jacket and the antenna coupling component.

10. The device of claim 1 wherein the antenna coupling component is dimensioned to maximize an amount of electromagnetic radiation emitted by the antenna coupling component when the radio frequency feed component delivers radio frequency signals to the antenna coupling component.

11. A method comprising:
electrically coupling a printed circuit board (PCB) comprising a radio frequency feed component to a power source comprising a metallic jacket; and
coupling an antenna coupling component to the PCB and the power source such that that the antenna coupling component:
is coupled to the radio frequency feed component; and
is coupled to the metallic jacket such that radio frequency signals delivered to the antenna coupling component from the radio frequency feed component cause the metallic jacket to emit radio frequency radiation.

12. The method of claim 11, wherein coupling the antenna coupling component to the metallic jacket comprises capacitively coupling the antenna coupling component to the metallic jacket.

13. The method of claim 11, wherein coupling the antenna coupling component to the metallic jacket comprises electrically coupling the antenna coupling component to the metallic jacket.

14. The method of claim 11, further comprising coupling the antenna coupling component to the PCB such that radio frequency signals delivered to the antenna coupling component from the radio frequency feed component cause circuitry of the PCB to emit radio frequency radiation.

15. The method of claim 11, wherein the frequency of the radio frequency radiation is equal to or is greater than 2.4 GHz.

16. The method of claim 11, further comprising enclosing the PCB, the power source, and the antenna coupling component within a housing that is dimensioned to be worn about a finger of a user.

17. The method of claim 16, wherein the housing comprises a metallic bezel that is capable of conducting RF signals.

18. The method of claim 11, wherein the antenna coupling component is coupled to an anode region of the power source.

19. The method of claim 11, further comprising forming an insulating layer over the metallic jacket such that, when the antenna coupling component is coupled to the metallic jacket, the insulating layer is disposed between the metallic jacket and the antenna coupling component.

20. The method of claim 11, wherein the antenna coupling component is dimensioned to maximize an amount of electromagnetic radiation emitted by the antenna coupling component when the radio frequency feed component delivers radio frequency signals to the antenna coupling component.
